(19) United States
(12) Patent Application Publication
(10) Pub. No.: US 2018/0197731 A1
(43) Pub. Date: Jul. 12, 2018

(54) RESIST PATTERN COATING COMPOSITION INCLUDING VINYL GROUP- OR (METH) ACRYLOXY GROUP-CONTAINING POLYSILOXANE

(71) Applicant: NISSAN CHEMICAL INDUSTRIES, LTD., Tokyo (JP)

(72) Inventors: Shuhei SHIGAKI, Toyama-shi (JP); Rikimaru SAKAMOTO, Toyama-shi (JP); Makoto NAKAJIMA, Toyama-shi (JP); Wataru SHIBAYAMA, Toyama-shi (JP)

(73) Assignee: NISSAN CHEMICAL INDUSTRIES, LTD., Tokyo (JP)

(21) Appl. No.: 15/759,313

(22) PCT Filed: Sep. 9, 2016
(86) PCT No.: PCT/JP2016/076644

§ 371 Date: Mar. 12, 2018

(30) Foreign Application Priority Data
Sep. 11, 2015 (JP) 2015-180166

(51) Int. Cl. H01L 21/027; C09D 151/08; G03F 7/11; C08G 77/20

(52) U.S. Cl. CPC H01L 21/0274; C08G 77/20; G03F 7/11; C09D 151/085

(57) ABSTRACT

A composition to be applied onto a resist pattern comprising a polysiloxane obtained by hydrolytically condensing a hydrolyzable silane and a carboxylic ester solvent or an ether solvent, wherein the hydrolyzable silane includes a vinyl group- or (meth)acryloxy group-containing hydrolyzable silane. A hydrolyzable silane includes the vinyl group- or (meth)acryloxy group-containing hydrolyzable silane at a content of 20 to 100 mol % in the total hydrolyzable silane. A method for producing a semiconductor device, the method includes: a step (1) of applying a resist onto a substrate; a step (2) of exposing a resist film to light and subsequently developing the resist film to form a resist pattern; a step (3) of applying the composition as described above onto the resist pattern during the development or after the development; and a step (4) of removing the resist pattern by etching to reverse the pattern.

### TECHNICAL FIELD

The present invention relates, in a lithography process, to a composition including a vinyl group- or (meth)acryloxy group-containing polysiloxane used to be applied to a resist pattern in a process of being formed during development of a resist or a resist pattern after the development, and also relates to a technique of reversing a pattern by applying a coating agent containing the composition to fill the pattern with the coating agent, and then removing the resist by etching such as dry etching.

### BACKGROUND ART

As a recent problem due to a finer pattern, a phenomenon is known in which a resist pattern collapses at a developing step or a step of rinsing a developer, performed after exposure of a resist to light at a lithography step.

This pattern collapsing is considered to be caused by force acting on between patterns associated with a surface tension or a liquid flow when a developer or a rinse agent is dried, that is, Laplace force. This Laplace force may be generated to cause the pattern collapsing also when the developer or the rinse agent is removed outward with centrifugal force.

In order to solve such a problem, a pattern forming method is disclosed (see Patent Document 1) that is characterized by including a step of forming a resist film on a substrate; a step of selectively irradiating the resist film with an energy beam to form a latent image in the resist film; a step of supplying a developer (alkaline developer) onto the resist film to form a resist pattern from the resist film having the latent image formed therein; a step of supplying a rinse agent onto the substrate to replace the developer on the substrate with the rinse agent; a step of supplying onto the substrate a coating film material containing a solvent and a solute different from the resist film to replace at least part of the rinse agent on the substrate with the coating film material; a step of volatilizing the solvent in the coating film material to form a coating film covering the resist film on the substrate; a step of removing at least part of a surface of the coating film to expose at least part of an upper surface of the resist pattern and form a mask pattern including the coating film; and a step of processing the substrate with the mask pattern. In Patent Document 1, the resist pattern is embedded with water-soluble silicone, and thus when this method is used for a solvent developing process, embedding failure may occur or a resist pattern may dissolve similarly to the case of Patent Document 2 described later.

A method for producing a resist structure is disclosed (see Patent Document 2), characterized in that a photoresist layer irradiated with light is treated with an aqueous solution or an aqueous alcohol solution of polyfunctional amino or hydroxysiloxane, and is etched in oxygen-containing plasma. In Patent Document 2, a resist pattern is embedded with a silicon-containing composition simultaneously with formation of the resist pattern at developing and rinsing steps, whereby pattern collapsing can be prevented. However, water or water and 2-propanol are used therein as solvents for the silicon-containing composition, which do not mix with a general developer for solvent development, and thus embedding failure may occur. Even if the embedding can be completed, the resulting resist structure cannot be used as a photoresist for solvent development because the resist pattern for solvent development dissolves in 2-propanol. A method for forming a pattern is also disclosed in which after a resist pattern is formed with resist material containing a base generator, a silicon-containing substance is coated to form a crosslinked part and an uncrosslinked part of the silicon-containing substance, and the uncrosslinked part is removed. For the silicon-containing substance, a hydroxy group-containing organic group is used (see Patent Document 3). In Patent Document 3, after developing and rinsing steps, a developer and a rinse agent are dried to form a resist pattern, and thus when the size of the resist pattern is finer, the problem that the resist pattern collapses occurs.

### PRIOR ART DOCUMENTS

### Patent Documents

Patent Document 1: Japanese Patent Application Publication No. 2005-277052 (JP 2005-277052 A)

Patent Document 2: Japanese Patent Application Publication No. H7-50286 (JP 117-50286 A)

Patent Document 3: Japanese Patent Application Publication No. 2011-027980 (JP 2011-027980 A)

### SUMMARY OF THE INVENTION

### Problem to be Solved by the Invention

In the methods according to a prior art, a resist surface after being exposed to light is developed with a developer and is then rinsed with a rinse agent, the rinse agent is replaced with a coating agent containing a polymer component, a resist pattern is coated with the polymer component, and then the resist is removed by dry etching, whereby a reverse pattern is formed with the polymer component as the replacement. However, in the methods described above, when the resist is removed with a developer or a rinse agent to form the resist pattern, Laplace force may act thereby causing the pattern to collapse.

Furthermore, if the resist pattern becomes finer, pattern collapsing occurs again due to Laplace force also when the developer or the rinse agent is spin dried at the developing step or the rinse step.

The present invention provides a material for preventing such pattern collapsing and a method therefor.

Specifically, the present invention provides a composition including hydrolytically condensed polysiloxane that can be used for solvent developing process using a photoresist for solvent development. More specifically, the present invention provides a composition containing hydrolytically condensed polysiloxane with which a developer for solvent development or a rinse agent for solvent development can be replaced when a fine resist pattern is formed in a solvent developing process, in which the composition enables the resist pattern to be embedded without resist pattern collapsing, or without embedding failure of the resist pattern or dissolving of the resist pattern.

The present invention also provides a material that is applied onto resist patterns to fill space between the patterns with a coating agent including the siloxane polymer-containing composition, forms a polymer between the resist patterns after being dried, and allows the patterns to be reversed by gas etching in which difference in gas-etching rate between the resist patterns and the polymer formed therebetween is utilized.

As a solvent for the polysiloxane-containing composition that can be used for a solvent developing process, an acetic ester solvent needs to be selected in order to prevent the photoresist for solvent development from dissolving therein. However, a conventional siloxane polymer has low solubility in the acetic ester solvent, and thus a uniform siloxane polymer-containing solution could not be obtained therefrom.

### Means for Solving the Problem

As a result of studies to solve this problem, the inventors of the present invention found that a siloxane polymer obtained by hydrolytically condensing a hydrolyzable silane including a vinyl group- or (meth)acryloxy group-containing hydrolyzable silane has high solubility in an acetic ester solvent, and accordingly found that the siloxane polymer enables embedding of a resist pattern without causing a photoresist for solvent development to dissolve therein.

As a first aspect, the present invention relates to a composition to be applied onto a resist pattern comprising a polysiloxane obtained by hydrolytically condensing a hydrolyzable silane and a carboxylic ester solvent or an ether solvent, wherein the hydrolyzable silane includes a vinyl group- or (meth)acryloxy group-containing hydrolyzable silane.

As a second aspect, the present invention relates to the composition according to the first aspect, in which the hydrolyzable silane includes the vinyl group- or (meth)acryloxy group-containing hydrolyzable silane at a content of 20 to 100 mol % in the total hydrolyzable silane.

As a third aspect, the present invention relates to the composition according to the first aspect or the second aspect, in which the carboxylic ester solvent is an acetic ester. As a fourth aspect, the present invention relates to the composition according to the first aspect or the second aspect, in which the ether solvent is a dialkyl ether having a C₂₋₁₀ alkyl group.

As a fifth aspect, the present invention relates to the composition according to any one of the first aspect to the fourth aspect, in which the vinyl group- or (meth)acryloxy group-containing hydrolyzable silane is a hydrolyzable silane of Formula (1):

R¹ₐR²_{b}Si(R³)_{4-(a+b)} Formula (1)

(wherein R¹ is an organic group including a vinyl group or a (meth)acryloxy group and is bonded to a silicon atom through a Si—C bond; R² is an alkyl group, an aryl group, a halogenated alkyl group, a halogenated aryl group, or an alkenyl group, or an organic group having an epoxy group, an amyloyl group, a methacryloyl group, a mercapto group, or a cyano group and is bonded to a silicon atom through a Si—C bond; R³ is an alkoxy group, an acyloxy group, or a halogen group; a is an integer of 1 or 2; b is an integer of 0 or 1; and a+b is an integer of 1 or 2).

As a sixth aspect, the present invention relates to the composition according to any one of the first aspect to the fourth aspect, in which the hydrolyzable silane includes a hydrolyzable silane of Formula (1) and a hydrolyzable silane of Formula (2):

R⁴_{c}R⁵_{d}Si(R⁶)_{4-(c+d)} Formula (2)

(wherein R⁴ and R⁵ are each independently an alkyl group, an aryl group, a halogenated alkyl group, or a halogenated aryl group, or an organic group having an epoxy group, a mercapto group, or a cyano group and are bonded to a silicon atom through a Si—C bond; R⁶ is an alkoxy group, an acyloxy group, or a halogen group; each of c and d is an integer of 0 or 1; and c+d is an integer of 0 to 2).

As a seventh aspect, the present invention relates to the composition according to any one of the first aspect to the sixth aspect further comprising an acid or a base. As an eighth aspect, the present invention relates to the composition according to any one of the first aspect to the seventh aspect further comprising a surfactant.

As a ninth aspect, the present invention relates to the composition according to any one of the first aspect to the eighth aspect further comprising a photoacid generator.

As a tenth aspect, the present invention relates to a method for producing a semiconductor device, the method comprising: a step (1) of applying a resist onto a substrate; a step (2) of exposing a resist film to light and subsequently developing the resist film to form a resist pattern; a step (3) of applying the composition as described in any one of the first aspect to the ninth aspect onto the resist pattern during the development or after the development; and a step (4) of removing the resist pattern by etching to reverse the pattern.

As an eleventh aspect, the present invention relates to the method for producing according to the tenth aspect comprising a step (1-1) of forming a resist underlayer film on the substrate before the step (1).

As a twelfth aspect, the present invention relates to the method for producing according to the tenth aspect or the eleventh aspect comprising, after the step (3), a step (3-1) of etching back a surface of a coating film that is a cured product of the composition to expose a surface of the resist pattern.

### Effects of the Invention

The present invention makes it possible to provide a resist pattern coating composition with which a developer for solvent development or a rinse agent for solvent development can be replaced when a fine resist pattern is formed in a solvent developing process, and that contains polysiloxane obtained by hydrolytically condensing a hydrolyzable silane including a vinyl group- or (meth)acryloxy group-containing hydrolyzable silane.

More specifically, the present invention makes it possible to provide a resist pattern coating composition material that, in order to prevent resist patterns from collapsing when fine patterns are formed, is applied onto the resist patterns to fill space between the patterns with a polymer-containing coating agent (composition), forms a layer of a polymer in the composition between the resist patterns after being dried, and enables the patterns to be reversed by gas etching in which difference in gas-etching rate between the resist patterns and the polymer layer formed therebetween is utilized.

The composition containing polysiloxane according to the present invention prevents resist pattern from collapsing by using the above-described material and is excellent in embeddability of the resist patterns, and thus a resist pattern coating composition without embedding failure can be provided. Furthermore, solubility thereof in an acetic ester solvent in which a photoresist does not dissolve is high, and thus a uniform siloxane polymer-containing solution can be obtained, which enables the resist patterns to be embedded without dissolving of the resist patterns.

In the present invention, a resist that is being developed with the developer after exposure to light or has been developed is coated with a coating agent containing a polymer, whereby space between resist patterns is filled with a polymer that can newly form a pattern therebetween at a later step. Thus, this filling can be performed without collapsing of the original resist patterns, and a fine pattern that will not collapse can be formed by a reverse pattern (reversed pattern) formed in a later dry etching process.

### BRIEF DESCRIPTION OF THE DRAWINGS

FIG. 1 is a diagram illustrating a resist pattern of Example 13 formed on a silicon substrate, in a state after a solubility test performed with a composition of Preparation Example 1 on the resist pattern (at a magnification of 150000).

FIG. 2 is a diagram illustrating a resist pattern of Example 14 formed on a silicon substrate, in a state after a solubility test performed with a composition of Preparation Example 2 on the resist pattern (at a magnification of 150000).

FIG. 3 is a diagram illustrating a resist pattern of Example 15 formed on a silicon substrate, in a state after a solubility test performed with a composition of Preparation Example 3 on the resist pattern (at a magnification of 150000).

FIG. 4 is a diagram illustrating a resist pattern of Example 16 formed on a silicon substrate, in a state after a solubility test performed with a composition of Preparation Example 4 on the resist pattern (at a magnification of 150000).

FIG. 5 is a diagram illustrating a resist pattern of Example 17 formed on a silicon substrate, in a state after a solubility test performed with a composition of Preparation Example 5 on the resist pattern (at a magnification of 150000).

FIG. 6 is a diagram illustrating a resist pattern of Example 18 formed on a silicon substrate, in a state after a solubility test performed with a composition of Preparation Example 6 on the resist pattern (at a magnification of 150000).

FIG. 7 is a diagram illustrating a resist pattern of Example 19 formed on a silicon substrate, in a state after a solubility test performed with a composition of Preparation Example 7 on the resist pattern (at a magnification of 150000).

FIG. 8 is a diagram illustrating a resist pattern of Example 20 formed on a silicon substrate, in a state after a solubility test performed with a composition of Preparation Example 8 on the resist pattern (at a magnification of 150000).

FIG. 9 is a diagram illustrating a resist pattern of Example 21 formed on a silicon substrate, in a state after a solubility test performed with a composition of Preparation Example 9 on the resist pattern (at a magnification of 150000).

FIG. 10 is a diagram illustrating a resist pattern of Example 22 formed on a silicon substrate, in a state after a solubility test performed with a composition of Preparation Example 10 on the resist pattern (at a magnification of 150000).

FIG. 11 is a diagram illustrating a resist pattern of Example 23 formed on a silicon substrate, in a state after a solubility test performed with a composition of Preparation Example 11 on the resist pattern (at a magnification of 150000).

FIG. 12 is a diagram illustrating a resist pattern of Comparative Example 2 formed on a silicon substrate, in a state after a solubility test performed with a composition of Preparation Example 12 on the resist pattern (at a magnification of 150000).

FIG. 13 is a diagram illustrating a resist pattern of Example 24 formed on a silicon substrate, in a state after the resist pattern has been coated with a composition of Preparation Example 1, has been dried, and then has been gas etched to be reversed (at a magnification of 150000).

FIG. 14 is a diagram illustrating a resist pattern of Example 25 formed on a silicon substrate, in a state after the resist pattern has been coated with a composition of Preparation Example 10, has been dried, and then has been gas etched to be reversed (at a magnification of 150000).

### MODES FOR CARRYING OUT THE INVENTION

The present invention relates to a composition containing polysiloxane obtained by hydrolytically condensing a hydrolyzable silane and a carboxylic ester solvent or an ether solvent to be applied onto a resist pattern, in which the hydrolyzable silane includes a vinyl group- or (meth)acryloxy group-containing hydrolyzable silane.

The composition contains hydrolysis condensate (polysiloxane) dissolving in the solvent, and may contain hydrolyzable silane and/or hydrolysate thereof. The solid content thereof is 0.5 to 20.0% by mass, or 1.0 to 10.0% by mass. The solid content herein is the percentage of a remainder when the solvent is removed from the composition.

The content of the hydrolyzable silane, hydrolysate thereof, and hydrolysis condensate thereof (polysiloxane) in the solid content is 50 to 100% by mass, or 80 to 100% by mass.

The concentration of the hydrolyzable silane, the hydrolysate thereof, and the hydrolysis condensate thereof (polysiloxane) in the composition is 0.5 to 20.0% by mass.

In the present invention, the composition is a coating composition that is used after exposure of a resist, and thus the resist is exposed to light through a mask, and is filled with the composition during development or after the development.

The hydrolyzable silane, the hydrolysate thereof, and the hydrolysis condensate thereof each have a resin component different from that of the resist.

Thus, by selecting a gas type, the resist is selectively removed by dry etching and is filled with the hydrolysis condensate (polysiloxane) to form a new pattern for a later dry etching step.

In the present invention, as the carboxylic ester solvent, an acetic ester, a butyrate ester, or the like can be used.

Examples of the acetic ester include an acetic ester having a C₂₋₁₀ alkyl group, such as ethyl acetate, n-propyl acetate, n-butyl acetate, tert-butyl acetate, n-pentyl acetate, n-hexyl acetate, isoamyl acetate, and n-octyl acetate. Examples of the butyrate ester includes a butyrate ester having a C₂₋₁₀ alkyl group, such as ethyl butyrate, n-propyl butyrate, n-butyl butyrate, tert-butyl butyrate, n-pentyl butyrate, n-hexyl butyrate, isoamyl butyrate, and n-octyl butyrate.

Alternatively, an ether solvent can be used. As the ether solvent, a dialkyl ether having a C₂₋₁₀ alkyl group can be used. Examples of the solvent include an ether such as di-n-propyl ether, di-n-butyl ether, diisoamyl ether, and di-n-hexyl ether.

As the solvent, an acetic ester is preferred in particular.

Other than the carboxylic ester solvent and the ether solvent, another organic solvent can be contained not more than 50%.

In the present invention, the hydrolyzable silane used may include a vinyl group- or (meth)acryloxy group-containing hydrolyzable silane at a content of 20 to 100 mol % in the total hydrolyzable silane.

As the vinyl group- or (meth)acryloxy group-containing hydrolyzable silane, hydrolyzable silane of Formula (1) can be used.

In Formula (1), R¹ is an organic group including a vinyl group or a (meth)acryloxy group, and is bonded to a silicon atom through a Si—C bond. R² is an alkyl group, an aryl group, a halogenated alkyl group, a halogenated aryl group, or an alkenyl group, or an organic group having an epoxy group, an acryloyl group, a methacryloyl group, a mercapto group, or a cyano group and is bonded to a silicon atom through a Si—C bond. R³ is an alkoxy group, an acyloxy group, or a halogen group. a is an integer of 1 or 2, b is an integer of 0 or 1, and a+b is an integer of 1 or 2.

In the hydrolyzable silane of Formula (1), it is preferable that b be 0 and a be 1.

In R¹, the vinyl group may be directly bonded to a silicon atom, and the vinyl group may be bonded to a silicon atom through an organic group.

The (meth)acryloxy group refers to a methacryloxy group or an acryloxy group, and these acryloxy groups may directly bonded to a silicon atom, or may be bonded to a silicon atom through an organic group. When an organic group through which these functional groups are bonded to a silicon atom is used, an alkylene group is used as the organic group, examples thereof include a C₁₋₁₀ alkylene group, and a methylene group, an ethylene group, a n-propylene group, an i-propylene group, and a n-butylene group are preferably used.

In Formula (1), examples of the alkyl group in R² include a linear or branched alkyl group having a carbon atom number of 1 to 10, such as methyl group, ethyl group, n-propyl group, i-propyl group, n-butyl group, i-butyl group, s-butyl group, t-butyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, and 1-ethyl-2-methyl-n-propyl group.

Alternatively, an cyclic alkyl group may be used, and examples of a cyclic alkyl group having a carbon atom number of 1 to 10 include cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, and 2-ethyl-3-methyl-cyclopropyl group.

Examples of the halogenated alkyl group include organic groups obtained by substitution with a halogen atom such as fluorine, chlorine, bromine, or iodine in each of these alkyl groups above.

In Formula (1), examples of the aryl group in R² include a C₆₋₂₀ aryl group, examples of the halogenated aryl group therein include an organic group obtained by substitution with halogen atoms such as fluorine, chlorine, bromine, and iodine in this aryl group, and examples thereof include phenyl group, o-methylphenyl group, m-methylphenyl group, p-methylphenyl group, o-methylphenyl group, m-methylphenyl group, p-methylphenyl group, o-chlorophenyl group, m-chlorophenyl group, p-chlorophenyl group, o-fluorophenyl group, p-mercaptophenyl group, o-methoxyphenyl group, p-methoxyphenyl group, p-aminophenyl group, p-cyanophenyl group, a-naphthyl group, β-naphthyl group, o-biphenylyl group, m-biphenylyl group, p-biphenylyl group, 1-anthryl group, 2-anthryl group, 9-anthryl group, 1-phenanthryl group, 2-phenanthryl group, 3-phenanthryl group, 4-phenanthryl group, and 9-phenanthryl group.

In Formula (1), examples of the alkenyl group in R² include a C₂₋₁₀ alkenyl group, and examples thereof include ethenyl group, 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1 propenyl group, 1-methyl-2-propenyl group, 1-pentenyl group, 2-pentenyl group, 3-pentenyl group, 4-pentenyl group, 1-n-propylethenyl group, 1-methyl-1-butenyl group, l-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propyl ethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group.

In Formula (1), examples of the organic group having an epoxy group in R² include glycidoxymethyl group, glycidoxyethyl group, glycidoxypropyl group, glycidoxybutyl group, and epoxycyclohexyl group.

Examples of the organic group having an acryloyl group include acryloylmethyl group, acryloylethyl group, and acryloylpropyl group.

Examples of the organic group having a methacryloyl group include methacryloylmethyl group, methacryloylethyl group, and methacryloylpropyl group.

Examples of the organic group having a mercapto group include ethyl mercapto group, butyl mercapto group, hexyl mercapto group, and octyl mercapto group.

Examples of the organic group having a cyano group include cyanoethyl group and cyanopropyl group.

In Formula (1), examples of the alkoxy group in R³ include an alkoxy group having a linear, branched, or cyclic alkyl moiety having a carbon atom number of 1 to 20, and examples thereof include methoxy group, ethoxy group, n-propoxy group, i-propoxy group, n-butoxy group, i-butoxy group, s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, and 1-ethyl-2-methyl-n-propoxy group, and examples of the cyclic alkoxy group include cyclopropoxy group, cyclobutoxy group, 1-methyl-cyclopropoxy group, 2-methyl-cyclopropoxy group, cyclopentyloxy group, 1-methyl-cyclobutoxy group, 2-methyl-cyclobutoxy group, 3-methyl-cyclobutoxy group, 1,2-dimethyl-cyclopropoxy group, 2,3-dimethyl-cyclopropoxy group, 1-ethyl-cyclopropoxy group, 2-ethyl-cyclopropoxy group, cyclohexyloxy group, 1-methyl-cyclopentyloxy group, 2-methyl-cyclopentyloxy group, 3-methyl-cyclopentyloxy group, 1-ethyl-cyclobutoxy group, 2-ethyl-cyclobutoxy group, 3-ethyl-cyclobutoxy group, 1,2-dimethyl-cyclobutoxy group, 1,3-dimethyl-cyclobutoxy group, 2,2-dimethyl-cyclobutoxy group, 2,3-dimethyl-cyclobutoxy group, 2,4-dimethyl-cyclobutoxy group, 3,3-dimethyl-cyclobutoxy group, 1-n-propyl-cyclopropoxy group, 2-n-propyl-cyclopropoxy group, 1-i-propyl-cyclopropoxy group, 2-i-propyl-cyclopropoxy group, 1,2,2-trimethyl-cyclopropoxy group, 1,2,3-trimethyl-cyclopropoxy group, 2,2,3-trimethyl-cyclopropoxy group, 1-ethyl-2-methyl-cyclopropoxy group, 2-ethyl-1-methyl-cyclopropoxy group, 2-ethyl-2-methyl-cyclopropoxy group, and 2-ethyl-3-methyl-cyclopropoxy group.

In Formula (1), examples of the acyloxy group in R³ include a C₁₋₂₀ acyloxy group, and examples thereof include methylcarbonyloxy group, ethylcarbonyloxy group, n-propylcarbonyloxy group, i-propylcarbonyloxy group, n-butylcarbonyloxy group, i-butylcarbonyloxy group, s-butylcarbonyloxy group, t-butylcarbonyloxy group, n-pentylcarbonyloxy group, 1-methyl-n-butylcarbonyloxy group, 2-methyl-n-butylcarbonyloxy group, 3-methyl-n-butylcarbonyloxy group, 1,1-dimethyl-n-propylcarbonyloxy group, 1,2-dimethyl-n-propylcarbonyloxy group, 2,2-dimethyl-n-propylcarbonyloxy group, 1-ethyl-n-propylcarbonyloxy group, n-hexylcarbonyloxy group, 1-methyl-n-pentylcarbonyloxy group, 2-methyl-n-pentylcarbonyloxy group, 3-methyl-n-pentylcarbonyloxy group, 4-methyl-n-pentylcarbonyloxy group, 1,1-dimethyl-n-butylcarbonyloxy group, 1,2-dimethyl-n-butylcarbonyloxy group, 1,3-dimethyl-n-butylcarbonyloxy group, 2,2-dimethyl-n-butylcarbonyloxy group, 2,3-dimethyl-n-butylcarbonyloxy group, 3,3-dimethyl-n-butylcarbonyloxy group, 1-ethyl-n-butylcarbonyloxy group, 2-ethyl-n-butylcarbonyloxy group, 1,1,2-trimethyl-n-propylcarbonyloxy group, 1,2,2-trimethyl-n-propylcarbonyloxy group, 1-ethyl-1-methyl-n-propylcarbonyloxy group, 1-ethyl-2-methyl-n-propylcarbonyloxy group, phenylcarbonyloxy group, and tosylcarbonyloxy group.

In Formula (1), examples of the halogen group in R³ include halogen groups such as fluorine, chlorine, bromine, and iodine.

The hydrolyzable silane of Formula (1) can be exemplified below. In compounds exemplified below, T is a hydrolyzable group, which is an alkoxy group, an acyloxy group, or a halogen group, and examples thereof include examples described above. In particular, alkoxy groups such as a methoxy group and an ethoxy group are preferred.

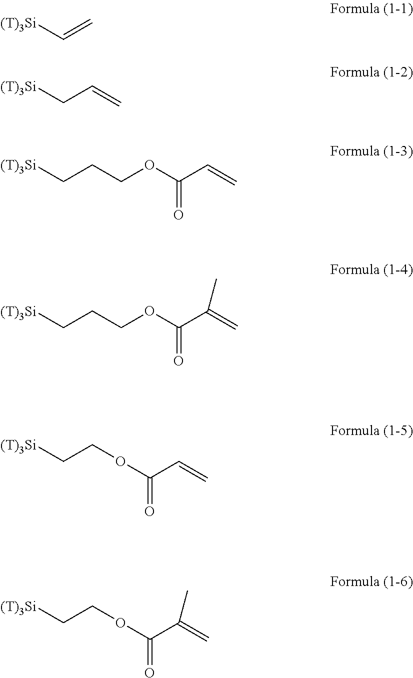

In the present invention, the hydrolyzable silane may include the hydrolyzable silane of Formula (1) and the hydrolyzable silane of Formula (2). The vinyl group- or (meth)acryloxy group-containing hydrolyzable silane of Formula (1) is preferably included at 20 to 100 mol % in the total hydrolyzable silane. For example, the hydrolyzable silane of Formula (1) and the hydrolyzable silane of Formula (2) can be used at a molar ratio of 100:0 to 20:80.

In Formula (2), R⁴ and R⁵ are each independently an alkyl group, an aryl group, a halogenated alkyl group, or a halogenated aryl group, or an organic group having an epoxy group, a mercapto group, or a cyano group, and are each bonded to a silicon atom through a Si—C bond. R⁶ is an alkoxy group, an acyloxy group, or a halogen group. As these groups, examples described above can be used. Each of c and d is an integer of 0 or 1, and c+d is an integer of 0 to 2.

Examples of the hydrolyzable silane of Formula (2) include tetramethoxysilane, tetrachlorosilane, tetraacetoxysilane, tetraethoxysilane, tetra-n-propoxysilane, tetraisopropoxysilane, tetra-n-butoxysilane, methyltrimethoxysilane, methyltriethoxysilane, methyltrichlorosilane, methyltriacetoxysilane, methyltripropoxysilane, methyltributoxysilane, methyltriamiloxysilane, methyltriphenoxysilane, methyltribenzyloxysilane, methyltriphenethyloxysilane, ethyltrimethoxysilane, ethyltriethoxysilane, phenyltrimethoxysilane, phenyltrichlorosilane, phenyltriacetoxysilane, phenyltriethoxysilane, γ-mercaptopropyltrimethoxysilane, γ-mercaptopropyltriethoxysilane, β-cyanoethyltriethoxysilane, dimethyldimethoxysilane, phenylmethyldimethoxysilane, dimethyldiethoxysilane, phenylmethyldiethoxysilane, dimethyldiacetoxysilane, γ-mercaptopropylmethyldimethoxysilane, and γ-mercaptomethyldiethoxysilane.

The hydrolysis condensate used in the present invention is exemplified below.

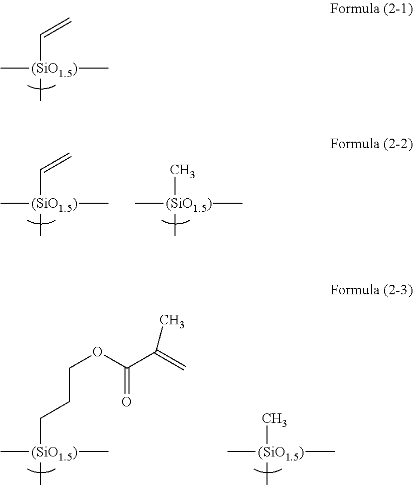

The hydrolysis condensate (polysiloxane) of the hydrolyzable silane of Formula (1) or the hydrolysis condensate (polysiloxane) of the hydrolyzable silane including the hydrolyzable silane of Formula (1) and the hydrolyzable silane of Formula (2) can yield condensate having a weight-average molecular weight of 1000 to 1000000 or 1000 to 100000.

This molecular weight is a molecular weight obtained by GPC analysis in terms of polystyrene.

As measurement conditions of GPC, for example, a GPC system (trade name HLC-8220GPC, manufactured by Tosoh Corporation), GPC columns (trade name Shodex KF803L, KF802, KF801, manufactured by Showa Denko K.K.), a column temperature of 40° C., tetrahydrofuran as eluent (elution solvent), a flow volume (flow rate) of 1.0 ml/min, and polystyrene (manufactured by Showa Denko K.K.) as a standard sample can be used.

For hydrolysis of alkoxysilyl groups, acyloxysilyl groups, or halogenated silyl groups, 0.5 to 100 mol, preferably 1 to 10 mol of water per 1 mol of the hydrolyzable group is used.

For the hydrolysis, a hydrolysis catalyst can be used, but the hydrolysis can be performed without a hydrolysis catalyst. When a hydrolysis catalyst is used, 0.001 to 10 mol, preferably 0.001 to 1 mol of a hydrolysis catalyst per 1 mol of the hydrolyzable group can be used.

The reaction temperature for the hydrolysis and condensation is generally 20 to 110° C.

The hydrolysis may be complete hydrolysis or may be partial hydrolysis. In other words, hydrolysate or a monomer may remain in the hydrolysis condensate.

For the hydrolysis and the condensation, a catalyst may be used.

Examples of the hydrolysis catalyst include a metal chelate compound, an organic acid, an inorganic acid, an organic base, and an inorganic base.

Examples of the metal chelate compound as the hydrolysis catalyst include titanium chelate compounds such as triethoxy mono(acetylacetonato)titanium, tri-n-propoxy mono(acetylacetonato)titanium, tri-i-propoxy mono(acetylacetonato)titanium, tri-n-butoxy mono(acetylacetonato)titanium, tri-sec-butoxy mono(acetylacetonato)titanium, tri-t-butoxy mono(acetylacetonato)titanium, diethoxy bis(acetylacetonato)titanium, di-n-propoxy bis(acetylacetonato)titanium, di-i-propoxy bis(acetylacetonato)titanium, di-n-butoxy bis(acetylacetonato)titanium, di-sec-butoxy bis(acetylacetonato)titanium, di-t-butoxy bis(acetylacetonato)titanium, monoethoxy tris(acetylacetonato)titanium, mono-n-propoxy tris(acetylacetonato)titanium, mono-i-propoxy tris(acetylacetonato)titanium, mono-n-butoxy tris(acetylacetonato)titanium, mono-sec-butoxy tris(acetylacetonato)titanium, mono-t-butoxy tris(acetylacetonato)titanium, tetrakis(acetylacetonato)titanium, triethoxy mono(ethylacetoacetate)titanium, tri-n-propoxy mono(ethylacetoacetate)titanium, tri-i-propoxy mono(ethylacetoacetate)titanium, tri-n-butoxy mono(ethylacetoacetate)titanium, tri-sec-butoxy mono(ethylacetoacetate)titanium, tri-t-butoxy mono(ethylacetoacetate)titanium, diethoxy bis(ethylacetoacetate)titanium, di-n-propoxy bis(ethylacetoacetate)titanium, di-i-propoxy bis(ethylacetoacetate)titanium, di-n-butoxy bis(ethylacetoacetate)titanium, di-sec-butoxy bis(ethylacetoacetate)titanium, di-t-butoxy bis(ethylacetoacetate)titanium, monoethoxy tris(ethylacetoacetate)titanium, mono-n-propoxy tris(ethylacetoacetate)titanium, mono-i-propoxy tris(ethylacetoacetate)titanium, mono-n-butoxy tris(ethylacetoacetate)titanium, mono-sec-butoxy tris(ethylacetoacetate)titanium, mono-t-butoxy tris(ethylacetoacetate)titanium, tetrakis(ethylacetoacetate)titanium, mono(acetylacetonato)tris(ethylacetoacetate)titanium, bis(acetylacetonato)bis(ethylacetoacetate)titanium, and tris(acetylacetonato)mono(ethylacetoacetate)titanium; zirconium chelate compounds such as triethoxy mono(acetylacetonato)zirconium, tri-n-propoxy mono(acetylacetonato)zirconium, tri-i-propoxy mono(acetylacetonato)zirconium, tri-n-butoxy mono(acetylacetonato)zirconium, tri-sec-butoxy mono(acetylacetonato)zirconium, tri-t-butoxy mono(acetylacetonato)zirconium, diethoxy bis(acetylacetonato)zirconium, di-n-propoxy bis(acetylacetonato)zirconium, di-i-propoxy bis(acetylacetonato)zirconium, di-n-butoxy bis(acetylacetonato)zirconium, di-sec-butoxy bis(acetylacetonato)zirconium, di-t-butoxy bis(acetylacetonato)zirconium, monoethoxy tris(acetylacetonato)zirconium, mono-n-propoxy tris(acetylacetonato)zirconium, mono-i-propoxy tris(acetylacetonato)zirconium, mono-n-butoxy tris(acetylacetonato)zirconium, mono-sec-butoxy tris(acetylacetonato)zirconium, mono-t-butoxy tris(acetylacetonato)zirconium, tetrakis(acetylacetonato)zirconium, triethoxy mono(ethylacetoacetate)zirconium, tri-n-propoxy mono(ethylacetoacetate)zirconium, tri-i-propoxy mono(ethylacetoacetate)zirconium, tri-n-butoxy mono(ethylacetoacetate)zirconium, tri-sec-butoxy mono(ethylacetoacetate)zirconium, tri-t-butoxy mono(ethylacetoacetate)zirconium, diethoxy bis(ethylacetoacetate)zirconium, di-n-propoxy bis(ethylacetoacetate)zirconium, di-i-propoxy bis(ethylacetoacetate)zirconium, di-n-butoxy bis(ethylacetoacetate)zirconium, di-sec-butoxy bis(ethylacetoacetate)zirconium, di-t-butoxy bis(ethylacetoacetate)zirconium, monoethoxy tris(ethylacetoacetate)zirconium, mono-n-propoxy tris(ethylacetoacetate)zirconium, mono-i-propoxy tris(ethylacetoacetate)zirconium, mono-n-butoxy tris(ethylacetoacetate)zirconium, mono-sec-butoxy tris(ethylacetoacetate)zirconium, mono-t-butoxy tris(ethylacetoacetate)zirconium, tetrakis(ethylacetoacetate)zirconium, mono(acetylacetonato)tris(ethylacetoacetate)zirconium, bis(acetylacetonato)bis(ethylacetoacetate)zirconium, tris(acetylacetonato)mono(ethylacetoacetate)zirconium; and aluminum chelate compounds such as tris(acetylacetonato)aluminum, tris(ethylacetoacetate)aluminum.

Examples of the organic acid as the hydrolysis catalyst include acetic acid, propionic acid, butanoic acid, pentanoic acid, hexanoic acid, heptanoic acid, octanoic acid, nonanoic acid, decanoic acid, oxalic acid, maleic acid, methyl malonic acid, adipic acid, sebacic acid, gallic acid, butyric acid, mellitic acid, arachidonic acid, shikimic acid, 2-ethyl hexoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, maleic acid, sulfonic acid, phthalic acid, fumaric acid, citric acid, and tartaric acid.

Examples of the inorganic acid as the hydrolysis catalyst include hydrochloric acid, nitric acid, sulfuric acid, fluorinated acid, and phosphoric acid.

Examples of the organic base as the hydrolysis catalyst include pyridine, pyrrole, piperazine, pyrrolidine, piperidine, picoline, trimethylamine, triethylamine, monoethanolamine, diethanolamine, dimethyl monoethanolamine, monomethyl diethanolamine, triethanolamine, diazabicyclooctane, diazabicyclononane, diazabicycloundecene, tetramethylammonium hydroxide, and tetraethylammonium hydroxide. Examples of the inorganic base include ammonia, sodium hydroxide, potassium hydroxide, barium hydroxide, and calcium hydroxide.

Examples of the organic solvent used for the hydrolysis include aliphatic hydrocarbon solvents such as n-pentane, i-pentane, n-hexane, i-hexane, n-heptane, i-heptane, 2,2,4-trimethylpentane, n-octane, i-octane, cyclohexane, methylcyclohexane; aromatic hydrocarbon solvents such as benzene, toluene, xylene, ethyl benzene, trimethyl benzene, methylethyl benzene, n-propyl benzene, i-propyl benzene, diethyl benzene, i-butyl benzene, triethyl benzene, di-i-propyl benzene, n-amyl naphthalene, trimethyl benzene; monoalcohol solvents such as methanol, ethanol, n-propanol, i-propanol, n-butanol, i-butanol, sec-butanol, t-butanol, n-pentanol, i-pentanol, 2-methyl butanol, sec-pentanol, t-pentanol, 3-methoxy butanol, n-hexanol, 2-methyl pentanol, sec-hexanol, 2-ethyl butanol, sec-heptanol, heptanol-3, n-octanol, 2-ethyl hexanol, sec-octanol, n-nonyl alcohol, 2,6-dimethyl heptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethyl carbinol, diacetone alcohol, and cresol; polyhydric alcohol solvents such as ethylene glycol, propylene glycol, 1,3-butylene glycol, pentanediol-2,4, 2-methyl pentanediol-2,4, hexanediol-2,5, heptanediol-2,4, 2-ethylhexanediol-1,3, diethylene glycol, dipropylene glycol, triethylene glycol, tripropylene glycol, and glycerin; ketone solvents such as acetone, methyl ethyl ketone, methyl-n-propyl ketone, methyl-n-butyl ketone, diethyl ketone, methyl-i-butyl ketone, methyl-n-pentyl ketone, ethyl-n-butyl ketone, methyl-n-hexyl ketone, di-i-butyl ketone, trimethyl nonanone, cyclohexanone, methylcyclohexanone, 2,4-pentanedione, acetonyl acetone, diacetone alcohol, acetophenone, and fenchone; ether solvents such as ethyl ether, i-propyl ether, n-butyl ether, n-hexyl ether, 2-ethylhexyl ether, ethylene oxide, 1,2-propylene oxide, dioxolane, 4-methyl dioxolane, dioxane, dimethyl dioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyl tetrahydrofuran; ester solvents such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxy butyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxy triglycol acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents such as N-methyl formamide, N,N-dimethyl formamide, N,N-diethyl formamide, acetamide, N-methyl acetamide, N,N-dimethyl acetamide, N-methyl propionamide, and N-methylpyrrolidone; and sulfur-containing solvents such as dimethyl sulfide, diethyl sulfide, thiophene, tetrahydro thiophene, dimethyl sulfoxide, sulfolane, and 1,3-propane sultone. These solvents may be used singly or in combination of two or more types.

After a solution of the hydrolysis condensate (polysiloxane) is obtained, the solvent and alcohol used for the hydrolysis described above can be removed and replaced with an acetic ester solvent (e.g., n-butyl acetate).

To the hydrolysis condensate (polysiloxane) solution, a carboxylic ester solvent such as an acetic ester solvent (e.g., n-butyl acetate) is added, and the solvent and alcohol used for the hydrolysis can be removed and replaced with the carboxylic ester solvent such as an acetic ester solvent.

The hydrolyzable silane is hydrolyzed and condensed in a solvent with a catalyst. From the obtained hydrolysis condensate (polymer), alcohol as a by-product, the hydrolysis catalyst used, and water can be simultaneously removed by distillation under reduced pressure or other operation. An acid catalyst and a base catalyst used for the hydrolysis can be removed by neutralization or ion exchange.

In the composition to be applied onto a resist pattern of the present invention, an inorganic acid, an organic acid, water, an alcohol, an organic amine, a photoacid generator, a metal oxide, a surfactant, or a combination thereof may be added in order to stabilize the composition containing the hydrolysis condensate.

Examples of the inorganic acid include hydrochloric acid, nitric acid, sulfuric acid, and phosphoric acid.

Examples of the organic acid include oxalic acid, malonic acid, methyl malonic acid, succinic acid, maleic acid, malic acid, tartaric acid, phthalic acid, citric acid, glutaric acid, citric acid, lactic acid, salicylic acid, and methanesulfonic acid. Among them, methane sulfonic acid, oxalic acid, maleic acid, octanoic acid, decanoic acid, octane sulfonic acid, decane sulfonic acid, dodecylbenzenesulfonic acid, phenolsulfonic acid, sulfosalicylic acid, camphor sulfonic acid, nonafluorobutane sulfonic acid, toluenesulfonic acid, cumene sulfonic acid, p-octylbenzene sulfonic acid, p-decylbenzene sulfonic acid, 4-octyl-2-phenoxy benzenesulfonic acid, and 4-carboxy benzenesulfonic acid, for example, are preferred. The content of the acid to be added is 0.5 to 15 parts by mass with respect to 100 parts by mass of the condensate (polysiloxane).

The alcohol to be added is preferably alcohol that is easily evaporated by heating after application, and examples thereof include methanol, ethanol, propanol, isopropanol (2-propanol), and butanol. The amount of the alcohol to be added may be 0.001 to 20 parts by mass with respect to 100 parts by mass of the composition to be applied onto the resist pattern.

Examples of the organic amine to be added include aminoethanol, methyl aminoethanol, N,N,N′,N′-tetramethyl ethylenediamine, N,N,N′,N′-tetraethyl ethylenediamine, N,N,N′,N′-tetrapropyl ethylenediamine, N,N,N′,N′-tetraisopropyl ethylenediamine, N,N,N′,N′-tetrabutyl ethylenediamine, N,N,N′,N′-tetraisobutyl ethylenediamine, N,N,N′,N′-tetramethyl-1,2-propylenediamine, N,N,N′,N′-tetraethyl-1,2-propylenediamine, N,N,N′,N′-tetrapropyl-1,2-propylenediamine, N,N,N′,N′-tetraisopropyl-1,2-propylenediamine, N,N,N′,N′-tetrabutyl-1,2-propylenediamine, N,N,N′,N′-tetraisobutyl-1,2-propylenediamine, N,N,N′,N′-tetramethyl-1,3-propylenediamine, N,N,N′,N′-tetraethyl-1,3-propylenediamine, N,N,N′,N′-tetrapropyl-1,3-propylenediamine, N,N,N′,N′-tetraisopropyl-1,3-propylenediamine, N,N,N′,N′-tetrabutyl-1,3-propylenediamine, N,N,N,N′-tetraisobutyl-1,3-propylenediamine, N,N,N′,N′-tetramethyl-1,2-butylenediamine, N,N,N′,N′-tetraethyl-1,2-butylenediamine, N,N,N′,N′-tetrapropyl-1,2-butylenediamine, N,N,N′,N′-tetraisopropyl-1,2-butylenediamine, N,N,N′,N′-tetrabutyl-1,2-butylenediamine, N,N,N′,N′-tetraisobutyl-1,2-butylenediamine, N,N,N′,N′-tetramethyl-1,3-butylenediamine, N,N,N′,N′-tetraethyl-1,3-butylenediamine, N,N,N′,N′-tetrapropyl-1,3-butylenediamine, N,N,N′,N′-tetraisopropyl-1,3-butylenediamine, N,N,N,N′-tetrabutyl-1,3-butylenediamine, N,N,N′,N′-tetraisobutyl-1,3-butylenediamine, N,N,N′,N′-tetramethyl-1,4-butylenediamine, N,N,N′,N′-tetraethyl-1,4-butylenediamine, N,N,N′,N′-tetrapropyl-1,4-butylenediamine, N,N,N′,N′-tetraisopropyl-1,4-butylenediamine, N,N,N′,N′-tetrabutyl-1,4-butylenediamine, N,N,N′,N′-tetraisobutyl-1,4-butylenediamine, N,N,N′,N′-tetramethyl-1,5-pentylenediamine, and N,N,N′,N′-tetraethyl-1,5-pentylenediamine. The content of the organic amine to be added may be 0.001 to 20 parts by mass with respect to 100 parts by mass of the composition to be applied onto the resist pattern.

Examples of the photoacid generator to be added include an onium salt compound, a sulfonimide compound, and a disulfonyldiazomethane compound.

Examples of the onium salt compound include iodonium salt compounds such as diphenyliodonium hexafluorophosphate, diphenyliodonium trifluoromethanesulfonate, diphenyliodonium nonafluoro-n-butanesulfonate, diphenyliodonium perfluoro-n-octanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds such as triphenylsulfonium hexafluoroantimonate, triphenylsulfonium nonafluoro-n-butanesulfonate, triphenylsulfonium camphorsulfonate, triphenylsulfonium trifluoromethanesulfonate, triphenylsulfonium adamantane carboxylate trifluoroethanesulfonate, triphenylsulfonium p-toluenesulfonate, triphenylsulfonium methanesulfonate, triphenylsulfonium phenolsulfonate, triphenylsulfonium nitrate, triphenylsulfonium maleate, bis(triphenylsulfonium) maleate, triphenylsulfonium hydrochloride, triphenylsulfonium acetate, triphenylsulfonium trifluoroacetate, triphenylsulfonium salicylate, triphenylsulfonium benzoate, triphenylsulfonium hydroxide.

Examples of the sulfonimide compound include N-(trifluoromethanesulfonyloxy)succinimide, N-(nonafluoro-n-butanesulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

The photoacid generator may be used singly or can be used in combination of two or more types.

When the photoacid generator is used, the content thereof is 0.01 to 30 parts by mass, 0.1 to 20 parts by mass, or 0.5 to 10 parts by mass with respect to 100 parts by mass of the condensate (polysiloxane).

The content of the metal oxide to be added may be 0.001 to 100 parts by mass with respect to 100 parts by mass of the composition to be applied onto the resist pattern.

Examples of the metal oxide or partial metal oxide to be added include hydrolysis condensate containing TiOx (titanium oxide, x=1 to 2), hydrolysis condensate containing WOx (tungsten oxide, x=1 to 3), hydrolysis condensate containing HfOx (hafnium oxide, x=1 to 2), hydrolysis condensate containing ZrOx (zirconium oxide, x=1 to 2), hydrolysis condensate containing AlOx (aluminium oxide, x=1 to 1.5), metatungstic acid, ammonium salt of metatungstic acid, silicotungstic acid, ammonium salt of silicotungstic acid, molybdic acid, ammonium salt of molybdic acid, phosphomolybdic acid, and ammonium salt of phosphomolybdic acid. The content of the metal oxide to be added may be 0.001 to 100 parts by mass with respect to 100 parts by mass of the composition to be applied onto the resist pattern. The metal oxide or the partial metal oxide can be obtained as hydrolysis condensate of metal alkoxide, and the partial metal oxide may include an alkoxide group.

Examples of the surfactant contained in the composition of the present invention include a nonionic surfactant, an anionic surfactant, a cationic surfactant, a silicon-based surfactant, and a UV-curable surfactant.

Examples of the surfactant include nonionic surfactants such as polyoxyethylene alkyl ethers such as polyoxyethylene lauryl ether, polyoxyethylene stearyl ether, polyoxyethylene cetyl ether, and polyoxyethylene oleyl ether;

polyoxyethylene alkylaryl ethers such as polyoxyethylene octylphenol ether and polyoxyethylene nonylphenol ether; polyoxyethylene polyoxypropylene block copolymers; sorbitan fatty acid esters such as sorbitan monolaurate, sorbitan monopalmitate, sorbitan monostearate, sorbitan monooleate, sorbitan trioleate, and sorbitan tristearate; and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants such as EFTOP EF301, EF303, and EF352 (trade name, manufactured by Tohkem Products Corp.), MEGAFAC F171, F173, R-08, R-30, R-40, and R-40N (manufactured by DIC CORPORATION), FLUORAD FC430 and FC431 (trade name, manufactured by Sumitomo 3M Ltd.), ASAHI GUARD AG710, and SURFLON S-382, SC101, SC102, SC103, SC104, SC105, and SC106 (trade name, manufactured by Asahi Glass Co., Ltd.); and silicon-based surfactants such as an organosiloxane polymer KP341 (trade name, manufactured by Shin-Etsu Chemical Co., Ltd.), and BYK302, BYK307, BYK333, BYK341, BYK345, BYK346, BYK347, and BYK348 (trade name, manufactured by BYK Additives & Instruments). The examples also include cationic surfactants such as distearyl dimethyl ammonium chloride, benzalkonium chloride, benzethonium chloride, cetylpyridinium chloride, hexadecyltrimethylammonium bromide, and dequalinium chloride; anionic surfactants such as octanoate, decanoate, octane sulfonate, decane sulfonate, palmitate, perfluorobutanesulfonate, and dodecylbenzenesulfonate; and UV-curable surfactants such as BYK307, BYK333, BYK381, BYK-UV-3500, BYK-UV-3510, and BYK-UV-3530 (trade name, manufactured by BYK Additives & Instruments).

These surfactants may be used singly or may be used in combination of two or more types. When the surfactant is used, the content thereof is 0.0001 to 5 parts by mass, 0.001 to 5 parts by mass, or 0.01 to 5 parts by mass with respect to 100 parts by mass of the condensate (polyorganosiloxane).

The composition containing the carboxylic ester solvent or the ether solvent and the polysiloxane obtained by hydrolytically condensing the hydrolyzable silane including a vinyl group- or (meth)acryloxy group-containing hydrolyzable silane of the present invention may be used in a solvent developing process using a photoresist for solvent development.

More specifically, the composition containing the polysiloxane of the present invention can be replaced with a developer for solvent development or a rinse agent for solvent development when a fine resist pattern is formed in the solvent developing process, and consequently the resist pattern can be embedded with the composition of the present invention without occurrence of resist pattern collapsing, without embedding failure of the resist pattern, or without dissolving of the resist pattern. The polymer-containing coating agent containing the composition of the present invention is applied onto resist patterns and space between the patterns is filled with this coating agent, a polymer is formed between the resist patterns after drying, and then the patterns can be reversed by gas etching in which difference in gas-etching rate between the resist patterns and the polymer formed therebetween is utilized.

Specifically, the coating agent containing pattern-forming siloxane polymer of the present invention is brought into contact with a resist surface that has been exposed to light with a mask, and space between the resist patterns is filled with this polymer, whereby collapsing of the resist patterns is prevented. Subsequently, surfaces of the resist patterns space between which is filled with the polymer are dry etched to remove the resist patterns, and the filling polymer thus forms new resist patterns. This can be called a reverse process.

The combination of the resist layer and the polymer to be filled is preferably selected such that dry-etching rates thereof vary depending on the gas types used for the dry etching. For example, when an acrylic resist material is used for the resist layer, a polyorganosiloxane material is preferably used as a polymer of the polymer layer to be filled.

In the present invention, a resist that has been developed after exposure to light is coated with the coating agent containing a polymer, whereby space between resist patterns is filled with a polymer that can newly form a pattern therebetween at a later step. Thus, this filling can be performed without collapsing of the original resist patterns, and a fine pattern that will not collapse can be formed by a reverse pattern (reversed pattern) in a later dry etching process.

During development with a developer after the exposure to light, substituting for the developer and the rinse agent, the coating agent (composition) of the present invention is caused to flow, whereby space between resist patterns is filled with the polymer, and thus a fine pattern that will not collapse can be formed by a reverse pattern formed in the later dry etching process.

When the coating agent applied onto the resist patterns coats the entire resist patterns, etching back is performed by dry etching to expose the resist surface, and then dry etching is performed with a gas (oxygen-based gas) that enables etching of the resist at a higher etching rate to reverse the pattern. Thus, the pattern can be reversed.

Therefore, the present invention also relates to a method for producing a semiconductor device, the method including a step (1) of applying a resist onto a substrate; a step (2) of exposing a resist film to light and subsequently developing the resist film to form a resist pattern; a step (3) of applying the above-described composition onto the resist pattern during development or after the development; and a step (4) of removing the resist pattern by etching to reverse a pattern.

A photoresist used at the step (1) is not limited as long as the photoresist is sensitive to light used for the exposure. Both a negative photoresist and a positive photoresist can be used.

Examples of the photoresist include: a positive photoresist formed of a novolac resin and 1,2-naphthoquinone diazide sulfonic acid ester; a chemically amplified photoresist formed of a binder having a group that is decomposed by an acid to increase an alkali dissolution rate and a photoacid generator; a chemically amplified photoresist formed of a low-molecular compound that is decomposed by an acid to increase the alkali dissolution rate of the photoresist, an alkali-soluble binder, and a photoacid generator; and a chemically amplified photoresist formed of a binder having a group that is decomposed by an acid to increase the alkali dissolution rate, a low-molecular compound that is decomposed by an acid to increase the alkali dissolution rate of the photoresist, and a photoacid generator. Specific examples thereof include APEX-E (trade name, manufactured by Shipley Company L.L.C), PAR710 (trade name, manufactured by Sumitomo Chemical Company, Limited), and SEPR430 (trade name, manufactured by Shin-Etsu Chemical Co., Ltd). The examples further include a fluorine atom-containing polymer-based photoresist as described in Proc. SPIE, Vol. 3999, 330-334 (2000), Proc. SPIE, Vol. 3999, 357-364 (2000), and Proc. SPIE, Vol. 3999, 365-374 (2000).

Furthermore, both of negative and positive electron beam resists can be used.

Examples of the electron beam resists include: a chemically amplified resist formed of an acid generator and a binder having a group that is decomposed by an acid to change the alkali dissolution rate; a chemically amplified resist formed of an alkali-soluble binder, an acid generator, and a low-molecular compound that is decomposed by an acid to change the alkali dissolution rate of the resist; a chemically amplified resist formed of an acid generator, a binder having a group that is decomposed by an acid to change the alkali dissolution rate, and a low-molecular compound that is decomposed by an acid to change the alkali dissolution rate of the resist; a non-chemically amplified resist formed of a binder having a group that is decomposed by an electron beam to change the alkali dissolution rate; and a non-chemically amplified resist formed of a binder having a moiety that is cut by an electron beam to change the alkali dissolution rate. When these electron beam resists are used, a resist pattern can be formed similarly to the case when a photoresist is used with an electron beam as an irradiation source.

A resist solution is applied, and is then baked for 0.5 to 5 minutes at a baking temperature of 70 to 150° C., whereby a resist film having a thickness range of 10 to 1000 nm is obtained. Coating with a resist solution, a developer, or a coating material described below can be performed by spin coating, dipping, spraying, or other coating methods, and spin coating is particularly preferred. The resist is exposed to light through a predetermined mask. For the exposure to light, for example, KrF excimer laser (a wavelength of 248 nm), ArF excimer laser (a wavelength of 193 nm), EUV light (a wavelength of 13.5 nm), and an electron beam can be used. After the exposure to light, post exposure bake (PEB) may be performed if necessary. For the post exposure bake, a heating temperature is selected from a range of 70° C. to 150° C. and a heating time is selected from a range of 0.3 to 10 minutes appropriately.

Before the step (1), a step (1-1) of forming a resist underlayer film on a substrate may be included. The resist underlayer film prevents reflection and functions as an organic hard mask.

In other words, formation of a resist at the step (1) can be performed as the step (1-1) at which a resist underlayer film is formed on a semiconductor substrate and a resist is formed thereon.

At the step (1-1), a resist underlayer film is formed on a semiconductor substrate, a silicon hard mask may be formed thereon, and then a resist may be formed thereon.

The resist underlayer film used at the step (1-1) prevents diffuse reflection when an upper layer resist is exposed to light, and is used for the purpose of improving adhesion to a resist. As the resist underlayer film, for example, an acrylic resin or a novolac resin can be used. The resist underlayer film can form a coating film having a film thickness of 1 to 1000 nm on a semiconductor substrate.

The resist underlayer film used at the step (1-1) is a hard mask using an organic resin, for which a material having a high content of carbon and a low content of hydrogen is used. Examples of the material include a polyvinylnaphthalene resin, a carbazole novolac resin, a phenol novolac resin, and a naphthol novolac resin. These resins each can form a coating film having a film thickness of 5 to 1000 nm on a semiconductor substrate.

For a silicon hard mask used at the step (1-1), polysiloxane obtained by hydrolyzing hydrolyzable silane can be used. For example, polysiloxanes obtained by hydrolyzing tetraethoxysilane, methyltrimethoxysilane, and phenyltriethoxysilane can be exemplified. Each of these polysiloxanes can form a coating film having a film thickness of 5 to 200 nm on the resist underlayer film.

At the step (2), exposure to light through the predetermined mask is performed. For the exposure to light, KrF excimer laser (a wavelength of 248 nm), ArF excimer laser (a wavelength of 193 nm), and EUV (a wavelength of 13.5 nm), for example, can be used. After the exposure to light, post exposure bake may be performed if necessary. The post exposure bake is performed under conditions appropriately selected from a heating temperature range of 70° C. to 150° C. and a heating time range of 0.3 to 10 minutes.

Subsequently, development is performed with a developer. Conditions for the development are appropriately selected from a temperature range of 5 to 50° C. and a time range of 10 to 600 seconds.

In the present invention, an organic solvent is used as the developer. After the exposure to light, development is performed with the developer (solvent). Consequently, for example, when a positive photoresist is used, part of the photoresist that has not been exposed to light is removed, whereby a pattern of the photoresist is formed.

Examples of the developer include methyl acetate, n-butyl acetate, ethyl acetate, isopropyl acetate, amyl acetate, isoamyl acetate, ethyl methoxy acetate, ethyl ethoxy acetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Furthermore, a surfactant or the like may be added to these developers. Conditions for the development are appropriately selected from a temperature range of 5 to 50° C. and a time range of 10 to 600 seconds.

At the step (3), a coating composition of the present invention is applied onto the resist during development or after the development. At the step (3), the coating composition is heated and thus can be formed. This heating is performed at a baking temperature of 50 to 180° C. for 0.5 to 5 minutes.

In the present invention, after the step (3), a step (3-1) of etching back a surface of the coating film to expose a resist pattern surface may be included. By this additional step, the resist pattern surface and the surface of the coating composition match, and at the later step (4), because of the difference in gas-etching rate between the resist pattern and the coating composition, only the resist component is removed and the component of the coating composition remains, and consequently reverse of the pattern occurs. In the etching back, the resist pattern is exposed with a gas (e.g., fluorine-based gas) that can remove the coating composition.

At the step (4), the resist pattern is removed by etching to reverse the pattern. At the step (4), the dry etching is performed with a gas such as tetrafluoromethane, perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, or chlorine trifluoride. The dry etching is performed preferably with an oxygen-based gas in particular.

Consequently, the original resist pattern is removed, and a reverse pattern is formed with a pattern reverse-forming polymer contained in the coating composition.

### EXAMPLES

### Synthesis Example 1

82.5 g of vinyltrimethoxysilane (100 mol % in the total hydrolyzable silane) and 123 g of n-butyl acetate were put in a 500-ml flask. While this mixed solution in the flask was being stirred by a magnetic stirrer, 30.0 g of 0.01 mol/L acetic acid was dropped into the mixed solution. After the dropping, the flask was placed in an oil bath adjusted at 95° C., and the solution was caused to react under heated reflux for 12 hours. Subsequently, this reaction solution was cooled down to the room temperature, and water, hydrochloric acid, and methanol as a reaction by-product were distilled off from the reaction solution under reduced pressure to concentrate the reaction solution, whereby a n-butyl acetate solution of co-hydrolysis condensate (polysiloxane) was obtained. The solid-content concentration was adjusted to be 30% by mass in terms of solid residue at 140° C.

20 g of polymer solution thus prepared was put in 100-ml two-neck flask, the flask was placed in an oil bath adjusted at 100° C., and the polymer solution was caused to react under heated reflux for 12 hours. This obtained polymer corresponded to that of Formula (2-1), and the weight-average molecular weight Mw thereof measured by GPC in terms of polystyrene was 10000.

### Synthesis Example 2

16 g of 2-propanol, 32 g of tetrahydrofuran, 2.1 g of 35 wt % tetraethylammonium hydroxide aqueous solution, and 2.7 g of ultrapure water were put in a 100-ml single-neck eggplant-shaped flask, and 12.5 g of vinyltrimethoxysilane (100 mol % in the total hydrolyzable silane) was slowly dropped therein. After the dropping, the flask was placed in an oil bath adjusted at 90° C., and the solution was caused to react under heated reflux for 4 hours. Subsequently, this reaction solution was cooled down to the room temperature, and was put in a 300-ml separatory funnel. 80 g of n-butyl acetate, 4.5 g of 6 mol/L hydrochloric acid, and 40 g of ultrapure water were added therein, and separation was performed to remove an aqueous phase. 40 g of water was added, and operation of washing a n-butyl acetate phase with water was performed twice, whereby a n-butyl acetate solution containing 2-propanol, tetrahydrofuran, and methanol as a by-product was obtained. The 2-propanol, the tetrahydrofuran, and the methanol as a reaction by-product were distilled off from the reaction solution under reduced pressure to concentrate the reaction solution, whereby a n-butyl acetate solution of co-hydrolysis condensate (polysiloxane) was obtained.

This obtained polymer corresponded to that of Formula (2-1), and the weight-average molecular weight Mw thereof measured by GPC in terms of polystyrene was 4000.

### Synthesis Example 3

16 g of 2-propanol, 32 g of tetrahydrofuran, 5.2 g of 35 wt % tetraethylammonium hydroxide aqueous solution, and 0.6 g of ultrapure water were put in a 100-ml single-neck eggplant-shaped flask, and a mixed solution of 9.1 g of vinyltrimethoxysilane (50 mol % in the total hydrolyzable silane) and 10.9 g of methyltriethoxysilane (50 mol % in the total hydrolyzable silane) was slowly dropped therein. After the dropping, the flask was placed in an oil bath adjusted at 90° C., and the solution was caused to react under heated reflux for 4 hours. Subsequently, this reaction solution was cooled down to the room temperature, and was put in a 300-ml separatory funnel. 80 g of n-butyl acetate, 4.1 g of 6 mol/L hydrochloric acid, and 40 g of ultrapure water were added therein, and separation was performed to remove an aqueous phase. 40 g of water was added, and operation of washing a n-butyl acetate phase with water was performed twice, whereby a n-butyl acetate solution containing 2-propanol, tetrahydrofuran, and methanol as a by-product was obtained. The 2-propanol, the tetrahydrofuran, and the methanol as a reaction by-product were distilled off from the reaction solution under reduced pressure to concentrate the reaction solution, whereby a n-butyl acetate solution of co-hydrolysis condensate (polysiloxane) was obtained.

This obtained polymer corresponded to that of Formula (2-2), and the weight-average molecular weight Mw thereof measured by GPC in terms of polystyrene was 3000.

### Synthesis Example 4

16 g of 2-propanol, 32 g of tetrahydrofuran, and 9.9 g of 35 wt % tetraethylammonium hydroxide aqueous solution were put in a 100-ml single-neck eggplant-shaped flask, a mixed solution of 5.3 g of vinyltrimethoxysilane (30 mol % in the total hydrolyzable silane) and 14.7 g of methyltriethoxysilane (70 mol % in the total hydrolyzable silane) was slowly dropped therein. After the dropping, the flask was placed in an oil bath adjusted at 90° C., and the solution was caused to react under heated reflux for 4 hours. Subsequently, this reaction solution was cooled down to the room temperature, and was put in a 300-ml separatory funnel. 80 g of n-butyl acetate, 19.7 g of 6 mol/L hydrochloric acid, and 40 g of ultrapure water were added therein, and separation was performed to remove an aqueous phase. 40 g of water was added, and operation of washing a n-butyl acetate phase with water was performed twice, whereby a n-butyl acetate solution containing 2-propanol, tetrahydrofuran, and methanol as a by-product was obtained. The 2-propanol, the tetrahydrofuran, and the methanol as a reaction by-product were distilled off from the reaction solution under reduced pressure to concentrate the reaction solution, whereby a n-butyl acetate solution of co-hydrolysis condensate (polysiloxane) was obtained.

This obtained polymer corresponded to that of Formula (2-2), and the weight-average molecular weight Mw measured by GPC in terms of polystyrene was 1500.

### Synthesis Example 5

16 g of 2-propanol, 32 g of tetrahydrofuran, and 8.4 g of 35 wt % tetraethylammonium hydroxide aqueous solution were put in a 100-ml single-neck eggplant-shaped flask, and a mixed solution of 7.5 g of 3-(trimethoxysilyl)propyl methacrylate (30 mol % in the total hydrolyzable silane) and 12.5 g of methyltrimethoxysilane (70 mol % in the total hydrolyzable silane) was slowly dropped therein. After the dropping, the flask was placed in an oil bath adjusted at 90° C., and the solution was caused to react under heated reflux for 4 hours. Subsequently, this reaction solution was cooled down to the room temperature, and was put in a 300-ml separatory funnel. 80 g of n-butyl acetate, 16.7 g of 6 mol/L hydrochloric acid, and 40 g of ultrapure water were added therein, and separation was performed to remove an aqueous phase. 40 g of water was added, and operation of washing a n-butyl acetate phase with water was performed twice, whereby a n-butyl acetate solution containing 2-propanol, tetrahydrofuran, and methanol as a by-product was obtained. The 2-propanol, the tetrahydrofuran, and the methanol as a reaction by-product were distilled off from the reaction solution under reduced pressure to concentrate the reaction solution, whereby a n-butyl acetate solution of co-hydrolysis condensate (polysiloxane) was obtained.

This obtained polymer corresponded to that of Formula (2-3), and the weight-average molecular weight Mw measured by GPC in terms of polystyrene was 2000.

### Comparative Synthesis Example 1

49.5 g of tetraethoxysilane (50 mol % in the total hydrolyzable silane), 42.4 g of methyltriethoxysilane (50 mol % in the total hydrolyzable silane), and 138 g of acetone were put in a 500-ml flask. While this mixed solution in the flask was being stirred by a magnetic stirrer, 30.0 g of 0.01 mol/L acetic acid was dropped into the mixed solution. After the dropping, the flask was placed in an oil bath adjusted at 95° C., and the solution was caused to react under heated reflux for 12 hours. This reaction solution was cooled down to the room temperature, 184 g of 1-methoxy-2-propanol was added therein, and then water, hydrochloric acid, ethanol as a reaction by-product were distilled off from the reaction solution under reduced pressure to concentrate the reaction solution, whereby a 1-methoxy-2-propanol solution of co-hydrolysis condensate (polysiloxane) was obtained. The solid-content concentration was adjusted to be 30% by mass in terms of solid residue at 140° C.

20 g of polymer solution thus prepared was put in 100-ml two-neck flask, the flask was placed in an oil bath adjusted at 100° C., and the polymer solution was caused to react under heated reflux for 4 hours. The weight-average molecular weight Mw measured by GPC in terms of polystyrene was 6000.

[Solvent Replacement in Polysiloxane Solution]

### Replacement Example 1

10 g of the polymer solution obtained in Synthesis Example 1 above was put in a 100-ml single-neck eggplant-shaped flask, and n-butyl acetate as a solvent was distilled off under reduced pressure as much as possible. Subsequently, 20 g of tert-butyl acetate was added therein, and the solvent was distilled off under reduced pressure as much as possible. The above-described operation was further repeated three times, whereby a polymer solution in which the solvents were changed from n-butyl acetate to tert-butyl acetate was obtained.

### Replacement Example 2

10 g of the polymer solution obtained in Synthesis Example 1 above was put in a 100-ml single-neck eggplant-shaped flask, and n-butyl acetate as a solvent was distilled off under reduced pressure as much as possible. Subsequently, 20 g of pentyl acetate was added therein, and the solvent was distilled off under reduced pressure as much as possible. The above-described operation was further repeated three times, whereby a polymer solution in which the solvents were changed from n-butyl acetate to pentyl acetate was obtained.

### Replacement Example 3

10 g of the polymer solution obtained in Synthesis Example 1 above was put in a 100-ml single-neck eggplant-shaped flask, and n-butyl acetate as a solvent was distilled off under reduced pressure as much as possible. Subsequently, 20 g of n-hexyl acetate was added therein, and the solvent was distilled off under reduced pressure as much as possible. The above-described operation was further repeated three times, whereby a polymer solution in which the solvents were changed from n-butyl acetate to n-hexyl acetate was obtained.

### Replacement Example 4

10 g of the polymer solution obtained in Synthesis Example 1 above was put in a 100-ml single-neck eggplant-shaped flask, and n-butyl acetate as a solvent was distilled off under reduced pressure as much as possible. Subsequently, 20 g of butyl butyrate was added therein, and the solvent was distilled off under reduced pressure as much as possible. The above-described operation was further repeated three times, whereby a polymer solution in which the solvents were changed from n-butyl acetate to n-butyl butyrate was obtained.

### Replacement Example 5

10 g of the polymer solution obtained in Synthesis Example 1 above was put in a 100-ml single-neck eggplant-shaped flask, and n-butyl acetate as a solvent was distilled off under reduced pressure as much as possible. Subsequently, 20 g of diisoamyl ether was added therein, and the solvent was distilled off under reduced pressure as much as possible. The above-described operation was further repeated three times, whereby a polymer solution in which the solvents were changed from n-butyl acetate to diisoamyl ether was obtained.

### Replacement Example 6

10 g of the polymer solution obtained in Synthesis Example 1 above was put in a 100-ml single-neck eggplant-shaped flask, and n-butyl acetate as a solvent was distilled off under reduced pressure as much as possible. Subsequently, 20 g of dibutyl ether was added therein, and the solvent was distilled off under reduced pressure as much as possible. The above-described operation was further repeated three times, whereby a polymer solution in which the solvents were changed from n-butyl acetate to dibutyl ether was obtained.

### Comparative Replacement Example 1

10 g of the polymer solution obtained in Synthesis Example 1 described above was put in a 100-ml single-neck eggplant-shaped flask, and n-butyl acetate as a solvent was distilled off under reduced pressure as much as possible. Subsequently, 20 g of 1-methoxy-2-propanol was added therein, and the solvent was distilled off under reduced pressure as much as possible. The above-described operation was further repeated three times, whereby a polymer solution in which the solvents were changed from n-butyl acetate to 1-methoxy-2-propanol was obtained.

[Preparation of Coating Composition]

The polymer solutions obtained in Synthesis Example 1 to Synthesis Example 5, Replacement Example 1 to Replacement Example 6, Comparative Replacement Example 1, and Comparative Synthesis Example 1 described above were diluted with n-butyl acetate, tert-butyl acetate, pentyl acetate, n-hexyl acetate, butyl butyrate, diisoamyl ether, dibutyl ether, or 1-methoxy-2-propanol, whereby coating compositions were obtained. The content of each polymer given in Table 1 indicates the content of solid content when the solvent is removed from the polymer solution, not the content of the polymer solution. The content of each component is represented in parts by mass. In Table 1, n-butyl acetate, tert-butyl acetate, pentyl acetate, n-hexyl acetate, butyl butyrate, diisoamyl ether, dibutyl ether, and 1-methoxy-2-propanol are respectively abbreviated as NBA, TBA, NPA, NHA, NBB, DIAE, DBE, and PGME.

TABLE 1

| | Polymer | Solvent |
|---|---|---|
| Preparation Example 1 | Synthesis Example 1 | NBA |
| Content | 4 | 100 |
| Preparation Example 2 | Synthesis Example 2 | NBA |
| Content | 4 | 100 |
| Preparation Example 3 | Synthesis Example 3 | NBA |
| Content | 4 | 100 |
| Preparation Example 4 | Synthesis Example 4 | NBA |
| Content | 4 | 100 |
| Preparation Example 5 | Synthesis Example 5 | NBA |
| Content | 4 | 100 |
| Preparation Example 6 | Replacement Example 1 | TBA |
| Content | 4 | 100 |
| Preparation Example 7 | Replacement Example 2 | NPA |
| Content | 4 | 100 |
| Preparation Example 8 | Replacement Example 3 | NHA |
| Content | 4 | 100 |
| Preparation Example 9 | Replacement Example 4 | NBB |
| Content | 4 | 100 |
| Preparation Example 10 | Replacement Example 5 | DIAE |
| Content | 4 | 100 |
| Preparation Example 11 | Replacement Example 6 | DBE |
| Content | 4 | 100 |
| Preparation Example 12 | Comparative Replacement | PGME |
| | Example 1 | |
| Content | 4 | 100 |
| Preparation Example 13 | Comparative Synthesis | NBA/PGME |
| | Example 1 | |
| Content | 4 | 80/20 |

The following describes evaluation results when the coating compositions of the present invention were used.

[NBA Solubility of Coating Composition]

(NBA Solubility Evaluation of Coating Composition)

2 g of NBA was added into 2 g of each coating polysiloxane coating composition in Preparation Examples 1 to 12 and Comparative Example 1, and NBA solubility was evaluated as follows. Each coating composition was visually observed to determine the presence or absence of turbidity. Presence of passage through a filter having a pore diameter of 0.01 μm was also checked. Evaluation results are given in Table 2.

TABLE 2

| | Coating | Turbidity (Visual | |
|---|---|---|---|
| Example | Composition | Observation) | 0.01 μm Filter |
| Example 1 | Preparation | Absent | Passed |
| | Example 1 | | |
| Example 2 | Preparation | Absent | Passed |
| | Example 2 | | |
| Example 3 | Preparation | Absent | Passed |
| | Example 3 | | |
| Example 4 | Preparation | Absent | Passed |
| | Example 4 | | |
| Example 5 | Preparation | Absent | Passed |
| | Example 5 | | |
| Example 6 | Preparation | Absent | Passed |
| | Example 6 | | |
| Example 7 | Preparation | Absent | Passed |
| | Example 7 | | |
| Example 8 | Preparation | Absent | Passed |
| | Example 8 | | |
| Example 9 | Preparation | Absent | Passed |
| | Example 9 | | |
| Example 10 | Preparation | Absent | Passed |
| | Example 10 | | |
| Example 11 | Preparation | Absent | Passed |
| | Example 11 | | |
| Example 12 | Preparation | Absent | Passed |
| | Example 12 | | |
| Comparative | Preparation | Present | Not Passed |
| Example 1 | Example 13 | | |

[Photoresist Solubility of Coating Composition]

(Test of Resistance of Photoresist to Coating Composition)

A resist underlayer film-forming composition (resist underlayer film-forming composition containing a polymer having an isocyanuric acid skeleton) was applied by a spinner onto a silicon substrate onto which SiON was evaporated, and was heated at 240° C. for 60 seconds to form a resist underlayer film having a film thickness of 30 nm. Onto this film, a resist solution for ArF negative development (trade name: FAiRS-9521V10K, manufactured by Fuji Corporation) was applied by a spinner. This film was heated on a hot plate at 110° C. for 90 seconds, whereby a resist film having a film thickness of 85 nm was formed. With an ArF excimer laser exposure apparatus (S307E, manufactured by Nikon Corporation), the resist film was exposed to light under predetermined conditions. After the exposure to light in order to obtain a line width of 65 nm and a space width of 65 nm, heating (PEB) was performed at 110° C. for 90 seconds, and the silicon substrate was cooled down to the room temperature on a cooling plate. This resist pattern-formed substrate after the PEB was developed with n-butyl acetate, and then the coating composition of each of Preparation Example 1 to 12 was applied thereon without spin drying, whereby the n-butyl acetate used for the development was replaced with the coating composition. Subsequently, the silicon substrate was spun at 1500 rpm for 60 seconds to dry the solvent in the coating composition, whereby the resist pattern was embedded.

Onto the resist pattern substrate after being embedded with the coating composition, n-butyl acetate was applied onto the entire substrate again. After being let stand for 60 seconds, the substrate was spun at 3000 rpm for 30 seconds to remove n-butyl acetate and the coating composition dissolving in the n-butyl acetate, and then was heated at 100° C. to be dried.

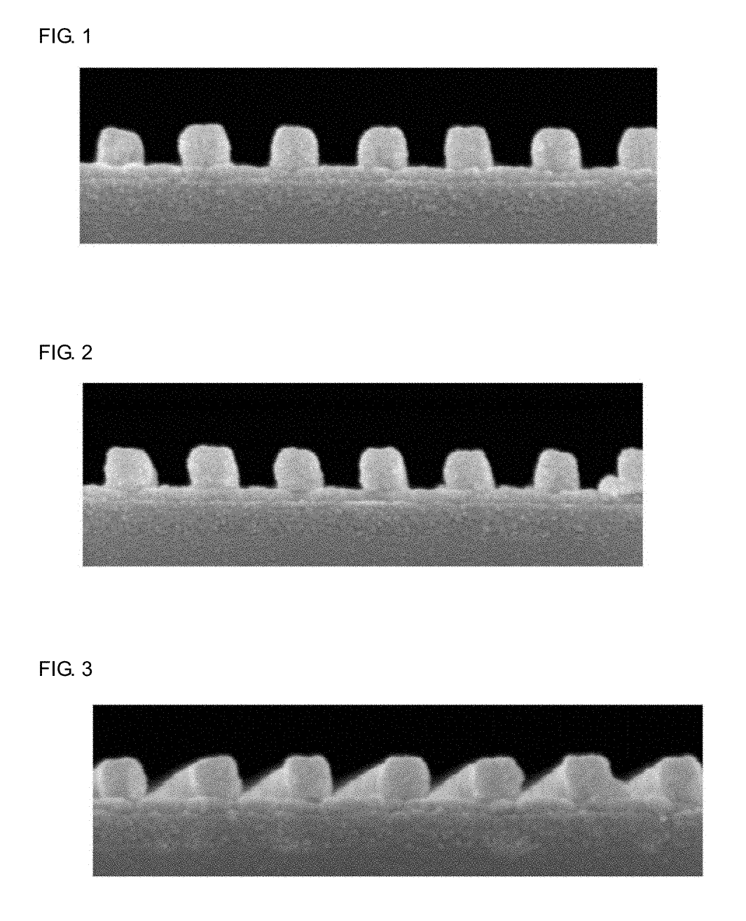

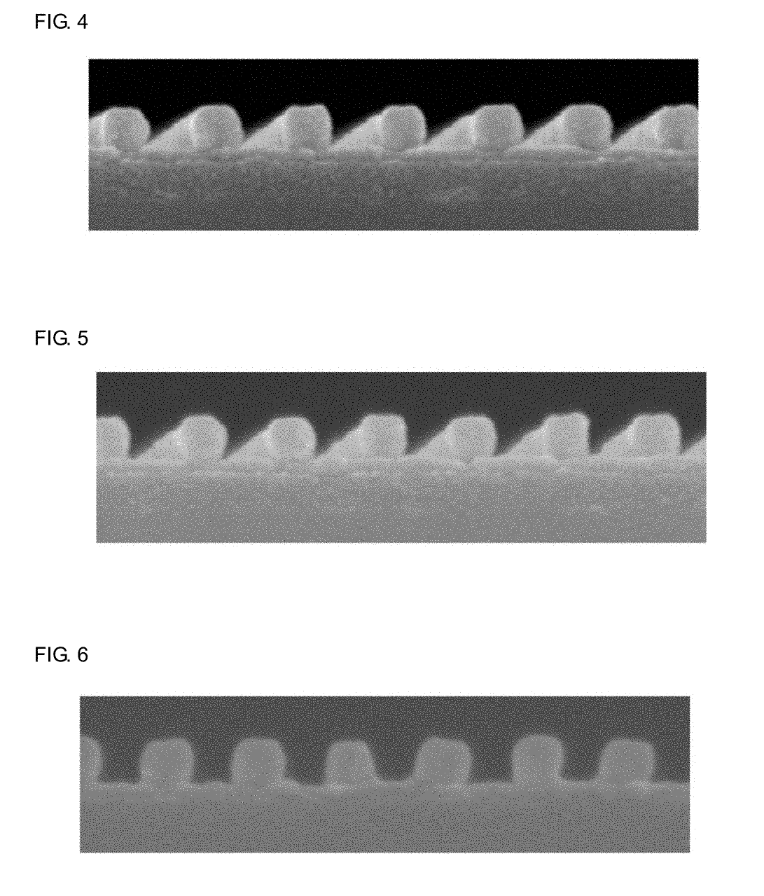

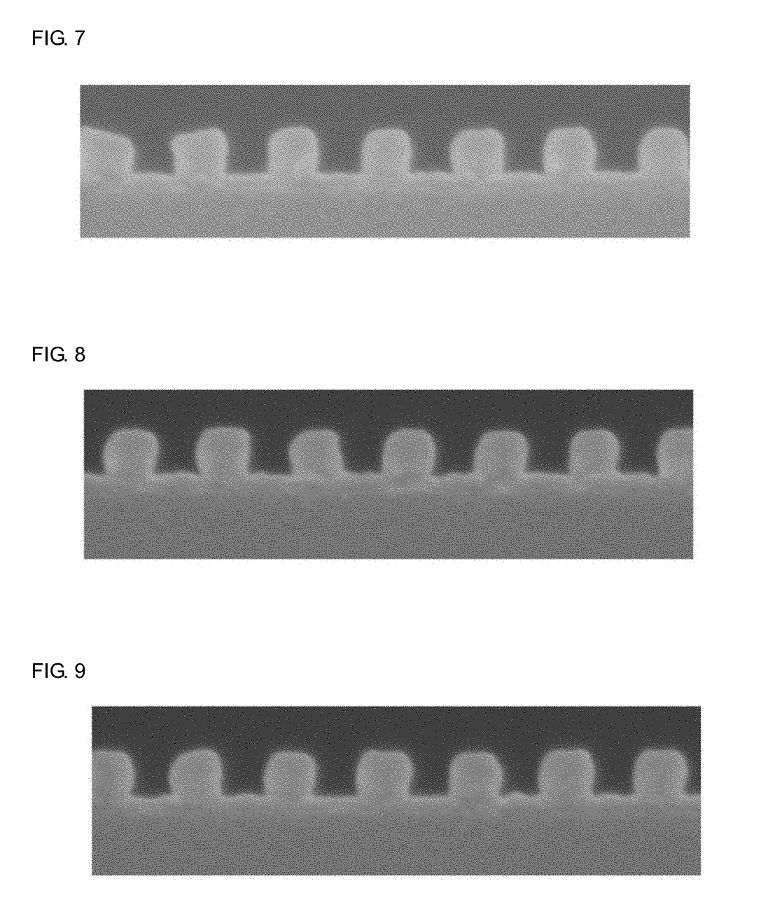

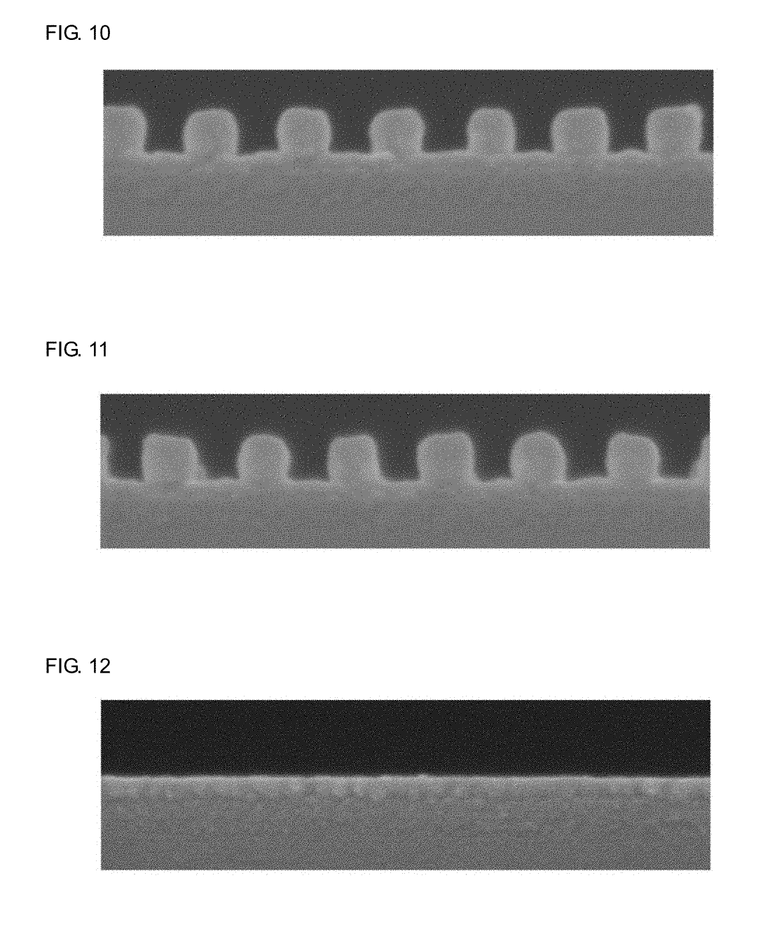

Respective cross-sections of the substrates onto which the coating compositions of Preparation Examples 1 to 12 were applied and from which the coating compositions were then removed with n-butyl acetate were observed with a SEM. Evaluation results thus obtained are given in Table 3. In Table 3, the cases when the photoresist did not dissolve and remained even after removal of the coating composition in the cross-sectional observation are indicated by “Undissolved”, and the case when the photoresist dissolved and was eliminated after removal of the coating composition is indicated by “Dissolved”. In FIGS. 1 to 12, the respective results of cross-sectional observation with a SEM are illustrated.

TABLE 3

| Example | Coating Composition | Photoresist Solubility |
|---|---|---|
| Example 13 | Preparation Example 1 | Undissolved |
| Example 14 | Preparation Example 2 | Undissolved |
| Example 15 | Preparation Example 3 | Undissolved |
| Example 16 | Preparation Example 4 | Undissolved |
| Example 17 | Preparation Example 5 | Undissolved |
| Example 18 | Preparation Example 6 | Undissolved |
| Example 19 | Preparation Example 7 | Undissolved |
| Example 20 | Preparation Example 8 | Undissolved |
| Example 21 | Preparation Example 9 | Undissolved |
| Example 22 | Preparation Example 10 | Undissolved |
| Example 23 | Preparation Example 11 | Undissolved |
| Comparative | Preparation Example 12 | Dissolved |
| Example 2 | | |

As can be seen from the results above, each coating composition of the present invention, when being applied onto a resist pattern, can be embedded in space between patterns of the resist pattern without dissolving of the resist pattern.

[Evaluation of Pattern Reverse of Coating Composition]

(Evaluation of Pattern Reverse Caused by Embedding of Resist Pattern with Coating Composition and Dry Etching)

A resist underlayer film-forming composition (resist underlayer film-forming composition containing a novolac resin) was applied onto a silicon substrate by a spinner, and was heated at 240° C. for 60 seconds to form a resist underlayer film having a film thickness of 20 nm. Onto this film, a resist solution for EUV negative development (manufactured by Fuji Corporation) was applied by a spinner. This film was heated on a hot plate, whereby a resist film having a film thickness of 50 nm was formed. With EB Lithography System (F-125, manufactured by ELIONIX INC.), lithography was performed on a resist film under predetermined conditions. After the exposure to light in order to obtain a line width of 25 nm and a space width of 25 nm, heating (PEB) was performed, and the silicon substrate was cooled down to the room temperature on a cooling plate. The silicon substrate was developed with a developer (n-butyl acetate) for negative development, and then the coating composition of Preparation Example 1 was applied thereon without spin drying, whereby the n-butyl acetate used for the development was replaced with the coating composition. Subsequently, the silicone substrate was spun at 1500 rpm for 60 seconds and was heated at 100° C., whereby the resist pattern was embedded.

A coating film formed with the coating composition of Preparation Example 1 was etched back by dry etching using a mixed gas of CF₄ (a flow rate of 50 sccm) and Ar (a flow rate of 200 sccm), whereby an upper portion of the resist pattern was exposed. Subsequently, the resist pattern was removed by dry etching using a mixed gas of O₂ (a flow rate of 10 sccm) and N₂ (a flow rate of 20 sccm), whereby a reverse pattern was obtained.

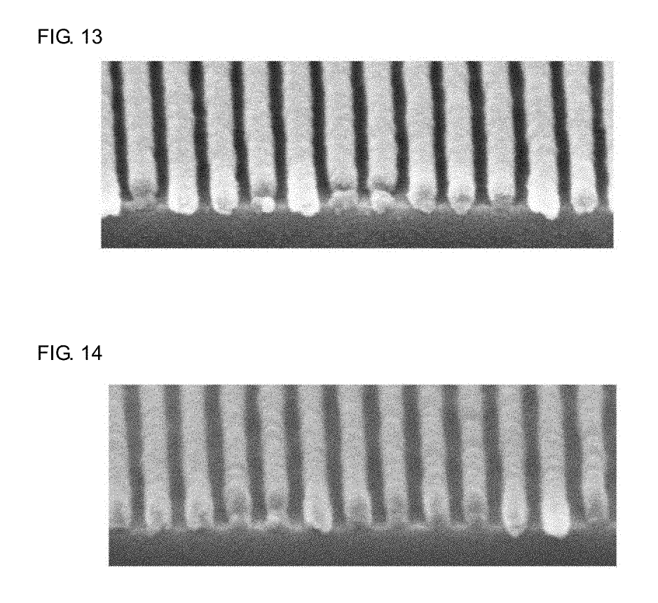

The reverse pattern obtained after dry etching after embedding with the coating composition of Preparation Example 1 was observed with a cross-section SEM. In FIGS. 13 and 14, states are illustrated in each of which the reverse pattern was formed without collapsing of the resist pattern.

TABLE 4

| | Coating Composition | Pattern Shape |
|---|---|---|
| Example 24 | Preparation Example 1 | Good |
| Example 25 | Preparation Example 10 | Good |

The composition containing polysiloxane obtained by hydrolytically condensing a hydrolyzable silane including a vinyl group- or (meth)acryloxy group-containing hydrolyzable silane of the present invention, when being applied onto a negative development-type resist pattern as a composition to be applied onto a negative development-type resist pattern, can be embedded in a space area of the resist pattern without dissolving of the negative development-type resist pattern. After application of a developer in a negative development process, when a coating composition containing the polysiloxane described above as a coating agent with which the developer can be replaced is used, a developer for negative development and the coating composition containing the polysiloxane are mixed uniformly. Thus, embedding in the space area of the resist pattern after the development can be directly performed without a step of drying the developer, which enables embedding without occurrence of resist pattern collapsing. After this pattern embedding, by selectively removing the negative development-type resist pattern by etching, a reverse pattern of the original negative development-type resist pattern can be obtained. Thus, the present invention can be used for a negative development-type coating composition that enables a negative development-type resist pattern to be embedded without pattern collapsing.

### INDUSTRIAL APPLICABILITY

The present invention provides a composition containing polysiloxane that can be applied onto a resist pattern in a solvent developing process.

The coating composition of the present invention can be applied onto resist patterns, and can be embedded in space between the resist patterns, and a coating film formed of the coating composition formed between the resist patterns can be used for reversing the patterns by gas etching utilizing difference in gas-etching rate between the coating film and the resist.

1. A composition to be applied onto a resist pattern comprising a polysiloxane obtained by hydrolytically condensing a hydrolyzable silane and a carboxylic ester solvent or an ether solvent, wherein the hydrolyzable silane includes a vinyl group- or (meth)acryloxy group-containing hydrolyzable silane.

2. The composition according to claim 1, wherein the hydrolyzable silane includes the vinyl group- or (meth)acryloxy group-containing hydrolyzable silane at a content of 20 to 100 mol % in the total hydrolyzable silane.

3. The composition according to claim 1, wherein the carboxylic ester solvent is an acetic ester.

4. The composition according to claim 1, wherein the ether solvent is a dialkyl ether having a C₂₋₁₀ alkyl group.

5. The composition according to claim 1, wherein the vinyl group- or (meth)acryloxy group-containing hydrolyzable silane is a hydrolyzable silane of Formula (1):
R¹ₐR²_{b}Si(R³)_{4-(a+b)} Formula (1)
wherein R¹ is an organic group including a vinyl group or a (meth)acryloxy group and is bonded to a silicon atom through a Si—C bond; R² is an alkyl group, an aryl group, a halogenated alkyl group, a halogenated aryl group, or an alkenyl group, or an organic group having an epoxy group, an acryloyl group, a methacryloyl group, a mercapto group, or a cyano group and is bonded to a silicon atom through a Si—C bond; R³ is an alkoxy group, an acyloxy group, or a halogen group; a is an integer of 1 or 2; b is an integer of 0 or 1; and a+b is an integer of 1 or 2.

6. The composition according to claim 1, wherein the hydrolyzable silane includes a hydrolyzable silane of Formula (1) and a hydrolyzable silane of Formula (2):
R⁴_{c}R⁵_{d}Si(R⁶)_{4-(c+d)} Formula (2)
wherein R⁴ and R⁵ are each independently an alkyl group, an aryl group, a halogenated alkyl group, or a halogenated aryl group, or an organic group having an epoxy group, a mercapto group, or a cyano group and are bonded to a silicon atom through a Si—C bond; R⁶ is an alkoxy group, an acyloxy group, or a halogen group; each of c and d is an integer of 0 or 1; and c+d is an integer of 0 to 2.

7. The composition according to claim 1, further comprising an acid or a base.

8. The composition according to claim 1, further comprising a surfactant.

9. The composition according to claim 1, further comprising a photoacid generator.

10. A method for producing a semiconductor device, the method comprising:
a step (1) of applying a resist onto a substrate;
a step (2) of exposing a resist film to light and subsequently developing the resist film to form a resist pattern;
a step (3) of applying the composition as claimed in claim 1 onto the resist pattern during the development or after the development; and
a step (4) of removing the resist pattern by etching to reverse the pattern.

11. The method for producing according to claim 10, comprising a step (1-1) of forming a resist underlayer film on the substrate before the step (1).

12. The method for producing according to claim 10, comprising, after the step (3), a step (3-1) of etching back a surface of a coating film that is a cured product of the composition to expose a surface of the resist pattern.
